(19) United States
(12) Patent Application Publication
(10) Pub. No.: US 2015/0069407 A1
(43) Pub. Date: Mar. 12, 2015

(54) GROUP III NITRIDE SEMICONDUCTOR MULTILAYER SUBSTRATE AND GROUP III NITRIDE SEMICONDUCTOR FIELD EFFECT TRANSISTOR

(71) Applicant: SHARP KABUSHIKI KAISHA, Osaka-shi, Osaka (JP)

(72) Inventors: Masakazu Matsubayashi, Osaka-shi (JP); Nobuaki Teraguchi, Osaka-shi (JP); Nobuyuki Ito, Osaka-shi (JP)

(73) Assignee: SHARP KABUSHIKI KAISHA, Osaka-shi, Osaka (JP)

(21) Appl. No.: 14/389,949

(22) PCT Filed: Apr. 19, 2013
(86) PCT No.: PCT/JP2013/061630

§ 371 Date: Oct. 1, 2014

(30) Foreign Application Priority Data
Apr. 26, 2012 (JP) 2012-101379

(51) Int. Cl. H01L 29/36; H01L 29/20; H01L 29/205; H01L 29/778

(52) U.S. Cl. CPC H01L 29/36; H01L 29/778; H01L 29/2003; H01L 29/205
USPC 257/76

(57) ABSTRACT

A group III nitride semiconductor multilayer substrate (100) includes a channel layer (5) which is a group III nitride semiconductor, a barrier layer (6) which is formed on the channel layer (5) to form a heterointerface in combination with the channel layer (5) and which is a group III nitride semiconductor, wherein in the barrier layer (6, 206), a Cu concentration in a region of 10 nm or less depths from its surface is 1.0×10¹⁰ (atomicity/cm²) or less.

### TECHNICAL FIELD

The present invention relates to a group III nitride semiconductor multilayer substrate, as well as a group III nitride semiconductor field effect transistor, in which, for example, an AlGaN layer is stacked on a GaN layer.

### BACKGROUND ART

A conventional group III nitride semiconductor device is known from PTL1 (JP 2009-117712 A), in which a GaN layer and an AlGaN layer are stacked sequentially on a Si substrate and moreover a 2DEG (2-dimensional electron gas) layer is formed in vicinity of a heterointerface between the GaN layer and the AlGaN layer.

In this group III nitride semiconductor device, an insulating film made of SiO₂ film or SiN film is formed on the AlGaN layer so as to suppress current collapse. Also in this group III nitride semiconductor device, an organic semiconductor layer that can substantially be regarded as an insulating film is formed between the AlGaN layer and a gate electrode so that the organic semiconductor layer feed carriers that cancel out carriers trapped to the surface of the AlGaN layer, aiming to suppress the current collapse.

However, such measures for suppressing the current collapse as described above do not suffice, and even further suppression of the current collapse has been being sought.

### CITATION LIST

### Patent Literature

PTL1: JP 2009-117712 A

### SUMMARY OF INVENTION

### Technical Problem

Accordingly, an object of the present invention is to provide a group III nitride semiconductor multilayer substrate, as well as a group III nitride semiconductor field effect transistor, capable of fulfilling further suppression of the current collapse.

### Solution to Problem

During manufacture of group III nitride semiconductor multilayer substrates, the present inventors found out that Cu is detected in the group III nitride semiconductor, and also found out that Cu mixed into the group III nitride semiconductor has an effect on the current collapse. Based on such findings by the present inventors as shown above, the present invention has been created.

That is, a group III nitride semiconductor multilayer substrate according to the present invention comprises:

a channel layer which is a group III nitride semiconductor; and

a barrier layer which is formed on the channel layer to form a heterointerface in combination with the channel layer and which is a group III nitride semiconductor, wherein

in the barrier layer,

a Cu concentration in a region of 10 nm or less depths from its surface is 1.0×10¹⁰ (atomicity/cm²) or less.

According to the group III nitride semiconductor multilayer substrate of this invention, the Cu concentration in the region of 10 nm or less depths from the surface of the barrier layer, which is the group III nitride semiconductor, is 1.0×10¹⁰ (atomicity/cm²) or less. As a result of this feature, the current collapse can be suppressed.

The term ‘current collapse’ refers to a phenomenon that on-resistance of a transistor in high-voltage operation becomes higher relative to on-resistance of the transistor in low-voltage operation.

Also, the term ‘surface’ refers to a surface of the barrier layer opposite to its channel layer-side surface. That is, the ‘surface’ refers to the upper-side surface of the barrier layer.

Also, the term ‘depth’ refers to a length of the barrier layer in a direction parallel to its layer thickness direction.

Accordingly, the term ‘region of 10 nm or less depths from the surface’ refers to a region of part of the barrier layer having a length of 10 nm or less in a direction parallel to the layer thickness direction of the barrier layer from its surface opposite to the channel-layer side surface toward the channel layer side.

In the group III nitride semiconductor multilayer substrate according to one embodiment,

the channel layer is made from GaN, and

the barrier layer is made from AlGaN.

According to this embodiment, there can be provided a group III nitride semiconductor multilayer substrate capable of high drain voltage operation and suitable for high-frequency, high-power FETs or the like.

In the group III nitride semiconductor multilayer substrate according to one embodiment,

the channel layer is made from GaN, and wherein

the barrier layer includes:

a layer made from AlGaN and positioned on one side closer to the channel layer; and

a cap layer made from GaN and positioned on the AlGaN layer.

According to this embodiment, by the cap layer made from GaN, oxidation of the nitride semiconductor layers (channel GaN layer, AlGaN barrier layer) can be prevented so that characteristic deteriorations due to oxidation of the nitride semiconductor layers can be suppressed.

A group III nitride semiconductor field effect transistor according to the present invention comprises:

the group III nitride semiconductor multilayer substrate, wherein

a source electrode, a drain electrode and a gate electrode are provided on the barrier layer, and

an insulating film is provided over a region where none of the source electrode, the drain electrode and the gate electrode is formed on the barrier layer.

According to the group III nitride semiconductor field effect transistor of this invention, the current collapse can be suppressed.

### Advantageous Effects of Invention

According to the group III nitride semiconductor multilayer substrate of the present invention, the Cu concentration in the region of 10 nm or less depths from the surface of the barrier layer is 1.0×10¹⁰ (atomicity/cm²) or less. As a result of this feature, the current collapse can be suppressed.

### BRIEF DESCRIPTION OF DRAWINGS

FIG. 1 is a sectional view of a nitride semiconductor device including a group III nitride semiconductor multilayer substrate according to a first embodiment of the present invention;

FIG. 2 is a characteristic chart showing a relationship between Cu concentration (atomicity/cm²) in the surface region of the AlGaN barrier layer and collapse value;

FIG. 3A is a schematic sectional view showing an aspect that electrons are running along an interface between channel GaN layer and AlGaN barrier layer in the nitride semiconductor device;

FIG. 3B is a schematic sectional view showing an aspect that electrons running along an interface between channel GaN layer and AlGaN barrier layer are trapped by Cu in a nitride semiconductor device according to a background art;

FIG. 3C is a schematic sectional view showing an aspect that electrons are running along the interface between channel GaN layer and AlGaN barrier layer without being trapped by Cu in the nitride semiconductor device including the group III nitride semiconductor multilayer substrate of the first embodiment;

FIG. 4A is a sectional view of a group III nitride semiconductor multilayer substrate according to a second embodiment of the present invention;

FIG. 4B is a sectional view showing a makeup of a barrier layer in the second embodiment;

FIG. 5 is a view schematically showing a configuration of an MOCVD device for fabricating the group III nitride semiconductor multilayer substrate of the first embodiment;

FIG. 6A is a sectional view showing an aspect that an O-ring is sandwiched against a flange of a gas introducing part of the MOCVD device;

FIG. 6B is a sectional view showing an aspect that a packing made from a Teflon-related material is sandwiched against a flange of a current introducing part of the MOCVD device;

FIG. 6C is a sectional view showing an aspect that an indium wire is sandwiched against a flange of a view port part of the MOCVD device; and

FIG. 6D is a sectional view showing an aspect that a copper gasket is sandwiched against a flange of an exhaust part of the MOCVD device.

### DESCRIPTION OF EMBODIMENTS

Hereinbelow, the present invention will be described in detail by way of embodiments thereof illustrated in the accompanying drawings.

### First Embodiment

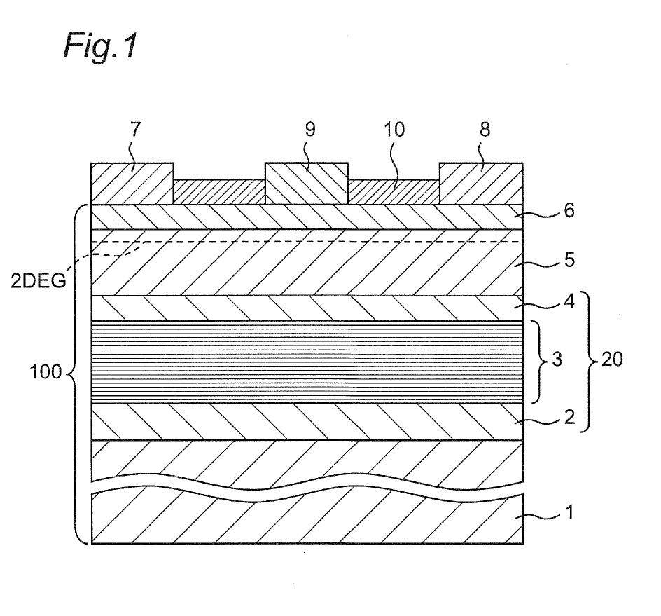

FIG. 1 is a sectional view of a nitride semiconductor device including a group III nitride semiconductor multilayer substrate 100 according to a first embodiment of the invention. This nitride semiconductor device is a GaN-related HFET (Hetero-junction Field Effect Transistor).

In the nitride semiconductor device, as shown in FIG. 1, an AlN seed layer 2, a superlattice layer 3, a carbon-doped GaN layer 4, a channel GaN layer 5 as an example of a channel layer, and an AlGaN barrier layer 6 as an example of a barrier layer are formed sequentially on a Si substrate 1. The AlN seed layer 2, the superlattice layer 3, and the carbon-doped GaN layer 4 constitute a buffer layer 20. Also, the Si substrate 1, the AlN seed layer 2, the superlattice layer 3, the carbon-doped GaN layer 4, the channel GaN layer 5 and the AlGaN barrier layer 6 constitute the group III nitride semiconductor multilayer substrate 100.

A source electrode 7 and a drain electrode 8 are formed on the AlGaN barrier layer 6 with a predetermined distance therebetween. The source electrode 7 and the drain electrode 8 are ohmic electrodes. Also, a gate electrode 9 is formed on the AlGaN barrier layer 6 and between the source electrode 7 and the drain electrode 8. The gate electrode 9 is a Schottky electrode. The source electrode 7 and the drain electrode 8 are made from Hf/Al/Hf/Au or Ti/Al/TiN or the like. The gate electrode 9 is made from WN/W/Au or the like.

An insulating film 10 made from SiN is formed on the AlGaN barrier layer 6 and over a region excluding the source electrode 7, the drain electrode 8 and the gate electrode 9.

In this embodiment, as an example, the film thickness of the buffer layer 20 is set to within a range of 3 μm to 7 μm, and the film thickness of the AlGaN barrier layer 6 is set to 30 nm. Also, the film thickness of the channel GaN layer 5 is set to 500 nm or more.

In this group III nitride semiconductor multilayer substrate 100 of the first embodiment, the Cu concentration in an upper-side region of the AlGaN barrier layer 6 is 1.0×10¹⁰ (atomicity/cm²) or less. More specifically, in the AlGaN barrier layer 6, the Cu concentration in a surface region of 10 nm or less depths from the surface is 1.0×10¹⁰ (atomicity/cm²) or less. In this case, the term ‘surface region’ refers to a region of part of the AlGaN barrier layer 6 having a length of 10 nm or less in a direction parallel to the layer thickness direction of the AlGaN barrier layer 6 from its gate electrode 9 side surface toward the channel layer side.

The Cu concentration in the surface region of the AlGaN barrier layer 6 was measured by the TXRF method (Total Reflection X-ray Fluorescence Method). The TXRF method is capable of efficiently detecting fluorescent X-rays from metal pollutants present on the substrate surface because fluorescent X-rays generated on the substrate side as well as scattered rays incident on the detector are reduced by applying an excited X-ray to the surface of the AlGaN barrier layer 6 at a lower angle (e.g., 0.1°) as compared with the XRF method (X-ray Fluorescence Method).

In the nitride semiconductor device constituted as described above, a two-dimensional electron gas (2DEG) is generated at the interface between the channel GaN layer and the AlGaN barrier layer 6, by which a channel is formed. This channel is controlled by applying a voltage to the gate electrode 9 so as to turn on and off the HFET including the source electrode 7, the drain electrode 8 and the gate electrode 9. This HFET is a normally-ON type transistor in which while a negative voltage is applied to the gate electrode 9, a depletion layer is formed in the channel GaN layer 5 under the gate electrode 9 so that the transistor is turned off, and in which while the voltage of the gate electrode 9 is zero volts, no depletion layer is formed in the channel GaN layer 5 under the gate electrode 9 so that the transistor is turned on.

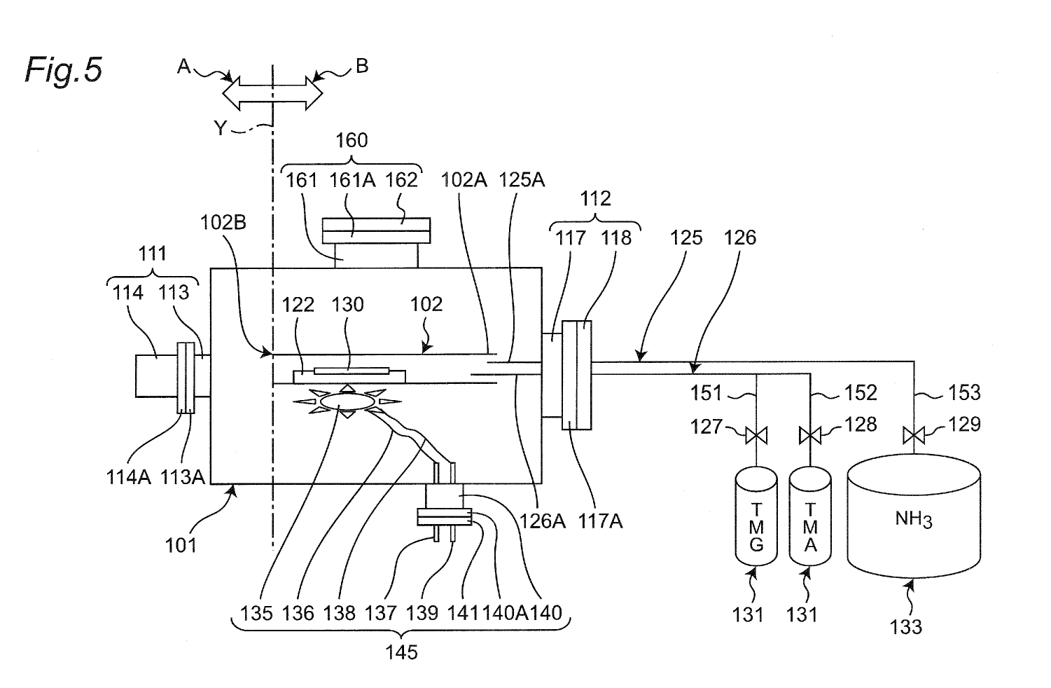

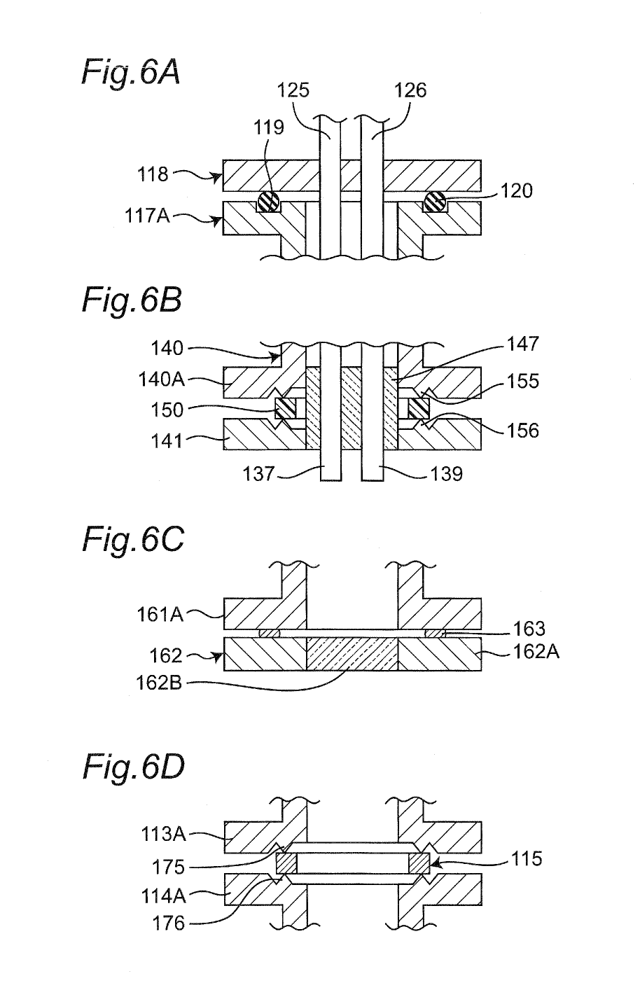

Next, an MOCVD (Metal Organic Chemical Vapor Deposition) device to be used for manufacture of the above-described group III nitride semiconductor multilayer substrate 100 will be described with reference to FIG. 5 and FIGS. 6A to 6D.

The MOCVD device includes a chamber 101 and a reaction part 102 provided in the chamber 101. As to the chamber 101 and the reaction part 102, at least their portions to be in contact with material gas are made from a non-copper material containing no copper such as stainless steel. The non-copper material refers to a material containing no copper.

In the chamber 101, an exhaust part 111 is provided downstream of the reaction part 102. Also in the chamber 101, a gas introducing part 112 is provided upstream of the reaction part 102.

The exhaust part 111 has an exhaust pipe 113 communicating with the chamber 101, and an exhaust duct 114. A flange 113A of the exhaust pipe 113 and a flange 114A of the exhaust duct 114 are tightened with tightening members such as bolts (not shown).

The gas introducing part 112 has a gas introducing cylinder 117 communicating with the chamber 101, and a lid member 118 tightened to the flange 117A of the gas introducing cylinder 117. The flange 117A of the gas introducing cylinder 117 and the lid member 118 are tightened with tightening members such as bolts (not shown). As to the gas introducing cylinder 117 and the lid member 118, at least their portions to be in contact with the material gas are made from a non-copper material such as stainless steel.

As shown in FIG. 6A, an O-ring 120 as a sealing member is sandwiched between the flange 117A and the lid member 118 of the gas introducing part 112. The O-ring 120 is placed at an annular groove 119 formed in an end face of the flange 117A. Also, the O-ring 120 is made from fluororubber such as Viton (trade name). In addition, although the tightening member (e.g., bolts) is omitted in FIG. 6A, the tightening member tightens the lid member 118 and the flange 117A at positions radially outer than the O-ring 120.

The flange 117A, the lid member 118, the O-ring 120 and the tightening member (not shown) constitute a sealing part. This sealing part is intended to hold a vacuum in the chamber 101 or confine the material gas to within the chamber 101. In addition, instead of the O-ring 120, a packing made from a later-described Teflon material or an indium wire may also be used as the sealing member. The indium wire is indeed effective as a sealing member for exhausting the interior of the chamber 101 to a high vacuum, but the above-described O-ring or a packing made from a Teflon (trade name) material such as PTFE (polytetrafluoroethylene) may also be used when high vacuum is unnecessary.

As shown in FIG. 5, a material gas introducing duct 125 and a material gas introducing duct 126 are provided through the lid member 118. As to the material gas introducing ducts 125, 126, at least their portions to be in contact with the material gas are made from a non-copper material such as stainless steel. Also, the material gas introducing duct 125 and the material gas introducing duct 126 are kept hermetic against the lid member 118 by welding. Fore end portions 125A, 126A of the material gas introducing ducts 125, 126 are positioned at an upstream-side opening 102A of the reaction part 102. Also, the material gas introducing duct 125 is connected to an NH₃ supply source 133 via a pipe joint (not shown), a pipe 153 and a flow regulating valve 129. Further, the material gas introducing duct 126 is connected to a TMG (trimethylgallium) supply source 131 via a pipe joint (not shown), a pipe 151 and a flow regulating valve 127. The material gas introducing duct 126 is also connected to a TMA (trimethylaluminum) supply source 132 via a pipe joint (not shown), a pipe 152 and a flow regulating valve 128. In addition, as to the individual pipe joints, the pipes 151, 152, 153 and the flow regulating valves 127, 128, 129, at least their portions to be in contact with the material gas are made from a non-copper material such as stainless steel.

Meanwhile, as shown in FIG. 6D, a copper gasket 115 as a sealing member is sandwiched between the flange 113A of the exhaust pipe 113 and the flange 114A of the exhaust duct 114 in the exhaust part 111. The copper gasket 115 is a copper ring having a specification such as ICF or CF as an example. The copper gasket 115 is sandwiched between an annular protrusion 175 formed in an end face of the flange 113A and an annular protrusion 176 formed in a rear face of the flange 114A. The copper gasket 115 is effective as a sealing member for high-vacuum exhaustion in the chamber 101. Also, the flange 113A and the flange 114A are tightened by tightening members (not shown) such as bolts. The flanges 113A, 114A, the copper gasket 115 and the tightening members (not shown) constitute a sealing part. An exhaust pump (not shown) is connected to the exhaust duct 114 of the exhaust part 111, and the interior of the chamber 101 is exhausted and reduced in pressure by this exhaust pump. The exhaust pipe 113 and the exhaust duct 114 of the exhaust part 111, although made from a non-copper material such as stainless steel in this embodiment, yet may also be made from a copper material containing copper.

In the reaction part 102, a mounting plate 122 is provided, and a substrate 130 is mounted on this mounting plate 122. The fore end portions 125A, 126A of the material gas introducing ducts 125, 126 are placed at the upstream-side opening 102A of the reaction part 102. The material gas introducing ducts 125, 126 extend through the gas introducing cylinder 117. As to the reaction part 102 and the mounting plate 122, at least their portions to be in contact with the material gas are made from a non-copper material such as stainless steel.

Also, a heater 135 for heating the mounting plate 122 is attached in the reaction part 102. The heater 135 is connected to current leading terminals 137, 139 with current supply lines 136, 138. The current supply lines 136, 138 and the current leading terminals 137, 139 were made from nickel as a non-copper material.

The current leading terminals 137, 139 are inserted into a terminal insertion tube 140 communicating with the chamber 101. The terminal insertion tube 140 has a flange 140A, and the flange 140A is tightened to a sealing lid 141 with a tightening member (not shown) such as bolts. As to the terminal insertion tube 140 and the sealing lid 141, at least their portions to be in contact with the material gas are made from a non-copper material such as stainless steel. The current supply lines 136, 138, the current leading terminals 137, 139, the terminal insertion tube 140 and the sealing lid 141 constitute a current introducing part 145.

As shown in FIG. 6B, an annular packing 150 as a sealing member is sandwiched between the flange 140A and the sealing lid 141. The annular packing 150 is made from a Teflon material such as PTFE (polytetrafluoroethylene). The packing 150 is sandwiched between an annular protrusion 155 formed in an end face of the flange 140A and an annular protrusion 156 formed in a rear face of the sealing lid 141. Also, the flange 140A and the sealing lid 141 are tightened with tightening members (not shown) such as bolts at positions radially outer than the packing 150. Also, the current leading terminals 137, 139 are inserted into a insulator ceramic 147 and fixed to the sealing lid 141 by silver soldering or the like so as to be hermetically fitted. The insulator ceramic 147 has high hermetic sealing property and high electrical dielectric property. The flange 140A, the sealing lid 141, the packing 150 and the tightening members (not shown) constitute a sealing part. This sealing part is intended to hold a vacuum in the chamber 101 or confine the material gas to within the chamber 101. In addition, instead of the sealing part using the packing 150 shown in FIG. 6B, a sealing part using the O-ring shown in FIG. 6A or a sealing part using the indium ring shown in FIG. 6C may also be adopted.

Also as shown in FIG. 5, in the chamber 101, a view port part 160 is provided so as to be positioned above the reaction part 102. The view port part 160 has a cylinder portion 161 communicating with the chamber 101, and a window portion 162 tightened to a flange 161A of the cylinder portion 161. As to the cylinder portion 161, at least its portion to be in contact with the material gas is made from a non-copper material such as stainless steel.

As shown in FIG. 6C, an indium wire 163 made from indium as a sealing member is sandwiched between the flange 161A of the cylinder portion 161 and a window frame portion 162a of the window portion 162. A heat-resistant glass 162B such as quartz glass is fitted into the window frame portion 162A. The heat-resistant glass 162B is fixed to the window portion 162 with an adhesive made from a non-copper material. As to the window frame portion 162A, at least its portion to be in contact with the material gas is made from a non-copper material such as stainless steel. The non-copper material refers to a material containing no copper.

The flange 161A and the window portion 162 are tightened by a tightening member (not shown) such as bolts. The flange 161A, the window portion 162, the indium wire 163 and the tightening member (not shown) constitute a sealing part. This sealing part is intended to hold a vacuum in the chamber 101 or confine the material gas to within the chamber 101. In addition, instead of the sealing part using the indium wire 163 shown in FIG. 6C, a sealing part using the O-ring shown in FIG. 6A or a sealing part using the packing made from a Teflon material shown in FIG. 6B may also be adopted.

As described above, as to the MOCVD device, its portions to be in contact with the material gas in an upstream-side region indicated by arrow B ranging from a downstream end 102B of the reaction part 102 indicated by one-dot chain line Y with respect to a flow of the material gas are made from non-copper materials containing no copper.

In this MOCVD device, the copper gasket 115 is used as the sealing member of the exhaust part 111 in the downstream-side region indicated by arrow A ranging from the downstream end 102B of the reaction part 102 indicated by the one-dot chain line Y. Alternatively, as the sealing member, an O-ring made from fluororubber, a PTFE packing or an indium ring may also be adopted as in the cases of the gas introducing part 112, the current introducing part 145 and the view port part 160. In addition, even if the copper gasket 115 is used in the downstream side of the reaction part 102 so that copper reacts with the material gas, copper is not trapped to the wafer but discharged out. Thus, the use of the copper gasket 115 does not matter. Further, since the sealing member by use of the O-ring made from fluororubber, the PTFE packing or the indium ring is lower in heat resistance than the copper gasket, it is desirable that an unshown cooling jacket or the like be attached to those sealing parts (flange, lid member, etc.) with the O-ring, the packing or the indium ring mounted so that a cooling medium (cooling water etc.) is circulated through the cooling jacket to cool the sealing parts.

Next, process for manufacturing the nitride semiconductor device shown in FIG. 1 with the MOCVD device in this embodiment will be explained below.

First, a Si substrate 1 is cleaned with a 10% HF (Hydrofluoric acid) solution and thereafter introduced into the MOCVD (Metal Organic Chemical Vapor Deposition) device.

The Si substrate 1 is heated to a substrate temperature of 1100° C. in a hydrogen atmosphere with a flow rate of 10 slm (Standard Liter per Minute: L/min.), thus subjected to surface cleaning. More strictly, hydrogen is introduced into the chamber 101 via a gas line, which is not shown in FIG. 5, other than gas lines for organic metal and ammonia.

Then, a buffer layer 20, a channel GaN layer 5, and an AlGaN barrier layer 6 are stacked sequentially on the Si substrate 1.

In this case, the AlN seed layer 2 was grown with a growth pressure of 13.3 kPa and a substrate temperature of 1100° C. In addition, as materials of AlN to form the AlN seed layer 2, TMA (trimethylaluminum) with a flow rate of 100 μmol/min. and NH₃ (ammonia) with a flow rate of 12.5 slm were supplied. The TMA is introduced from the TMA supply source 132 via the gas introducing part 112 into the chamber 101, while the NH₃ is introduced from an NH₃ supply source 133 via the gas introducing part 112 into the chamber 101. The substrate temperature is controlled by controlling the power of the heater 135.

The superlattice layer 3 was grown with a growth pressure of 13.3 kPa and a substrate temperature of 1100° C., as in the case of the AlN seed layer 2. For formation of the superlattice layer 3, materials to be supplied are alternately switched over so that AlN and Al_{0.1}Ga_{0.9}N are stacked in layers. As an example, a superlattice layer composed of a 3 nm thick layer of AlN and a 20 nm thick layer of Al_{0.1}Ga_{0.9}N is stacked in repetitions of 120 times to form the superlattice layer 3. As materials of Al_{0.1}Ga_{0.9}N, TMA with a flow rate of 80 μmol/min., TMG (trimethylgallium) with a flow rate of 720 μmol/min., and NH₃ with a flow rate of 12.5 slm are supplied. In addition, materials for AlN of the superlattice layer 3 were supplied as in the case of the AlN seed layer 2.

The carbon-doped GaN layer 4 was grown with a growth pressure of 13.3 kPa and a substrate temperature of 1100° C. as in the case of the AlN seed layer 2. In this case, as materials of GaN serving as the carbon-doped GaN layer 4, TMG with a flow rate of 720 μmol/min. and NH₃ with a flow rate of 12.5 slm are supplied.

The channel GaN layer 5 was grown with a growth pressure of 100 kPa and a substrate temperature of 1100° C. In this case, as materials of GaN serving as the channel GaN layer 5, TMG with a flow rate of 100 μmol/min. and NH₃ with a flow rate of 12.5 slm are supplied. The layer thickness of the channel GaN layer 5 was set to 1 μm as an example. The TMG is introduced from the TMG supply source 131 via the gas introducing part 112 into the chamber 101.

The AlGaN barrier layer 6 was grown with a growth pressure of 13.3 kPa and a substrate temperature of 1100° C. as in the case of the AlN seed layer 2. In this case, as materials of Al_{0.17}Ga_{0.83}N serving as the AlGaN barrier layer 6, TMA with a flow rate of 8 μmol/min., TMG with a flow rate of 50 μmol/min., and NH₃ with a flow rate of 12.5 slm are supplied.

Next, with use of epitaxial wafers fabricated as described above, a source electrode 7, a drain electrode 8 and a gate electrode 9 are formed on the AlGaN barrier layer 6. The manufacturing method for the source electrode 7, the drain electrode 8 and the gate electrode 9 is not particularly limited and a known method such as vapor deposition is used.

For example, the source/drain region is patterned and an ohmic electrode is deposited thereon. After lift-off, heat treatment for ohmic process is applied so that the source electrode 7 and the drain electrode 8 are formed. Conditions for this heat treatment, although varying depending on the film thickness of metal, were set to 800° C. for 1 min. in a nitrogen atmosphere in this embodiment. By this heat treatment, ohmic contact between the AlGaN barrier layer 6 and the source electrode 7 as well as ohmic contact between the AlGaN barrier layer 6 and the drain electrode 8 are obtained. Also, a distance between the source electrode 7 and the drain electrode 8 is adjusted depending on desired performance of the field effect transistor.

Next, a region where the gate electrode 9 is to be deposited is patterned and the gate electrode 9 is formed. For the gate electrode 9, while Pt, Ni, Pd, WN and the like are usable, WN was used in this embodiment. Thereafter, an insulating film 10 made from SiN is formed on the AlGaN barrier layer 6 by a known method such as plasma CVD.

In addition, the order for formation of the source electrode 7, the drain electrode 8, the gate electrode 9 and the insulating film 10 is not particularly limited, and the insulating film 10 may be formed first. Also, the ohmic electrode metal may be Hf/Al/Hf/Au or Ti/Al/Mo/Au.

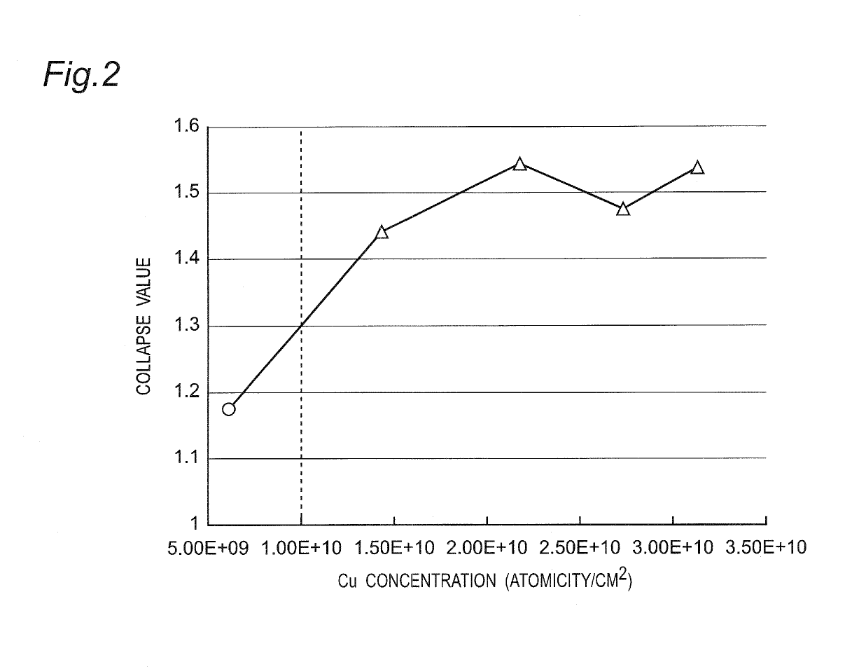

FIG. 2 shows a relationship between collapse value and Cu concentration (atomicity/cm²) in a surface region of 10 nm or less depths from the surface of the AlGaN barrier layer 6 in the nitride semiconductor device. In FIG. 2, E+09, E+10 in the horizontal axis represent 10⁹, 10¹⁰, respectively.

The collapse value is a value expressed by a ratio of on-resistance R1 to on-resistance R2 (R2/R1). The on-resistance R1 is a value resulting when a voltage of 1 V is applied to between the source electrode 7 and the drain electrode 8. The on-resistance R2 is obtained through the steps of applying a voltage of 500 V to between the source electrode 7 and the drain electrode 8 in an off state in which a negative voltage is applied to the gate electrode 9, and thereafter applying a voltage of 1 V to between the source electrode 7 and the drain electrode 8 in an on state in which the voltage of the gate electrode 9 is set to zero volts, where in this state, the on-resistance R2 results at a time point when 5 microseconds have elapsed after a switchover from the off state to the on state. It is noted that the on-resistance is defined by device size (e.g., the distance between the source electrode 7 and the drain electrode 8, the area of electrodes).

In one example of the group III nitride semiconductor multilayer substrate 100 fabricated with the MOCVD device described above with reference to FIG. 5, the Cu concentration (atomicity/cm² in n the surface region of the AlGaN barrier layer 6, as shown by the plot of 0 mark, was 6.1×10⁹ (atomicity/cm²), which is lower than 1.0×10¹⁰ (atomicity/cm²). Also, in another example of the group III nitride semiconductor multilayer substrate fabricated by the same process as described above with the MOCVD device, the Cu concentration (atomicity/cm² in n the surface region of the AlGaN barrier layer 6 was under 3×10⁹ (atomicity/cm²), which is a detection limit by the TXRF method.

Meanwhile, in a nitride semiconductor multilayer substrate of the comparative example fabricated with a conventionally available MOCVD device, in which copper was used at such portions as the sealing members of the gas introducing part, the current introducing part and the view port part as well as the portion of the current leading terminals and the like unlike the MOCVD device described above with reference to FIG. 5, the Cu concentration (atomicity/cm²) in the surface region of the AlGaN barrier layer, as indicated by plots of Δ mark in FIG. 2, was 1.44×10¹⁰ (atomicity/cm²), 2.18×10¹⁰ (atomicity/cm²), 2.74×10¹⁰ (atomicity/cm²), or 3.13×10¹⁰ (atomicity/cm²), where all of the values were over 1.0×10¹⁰ (atomicity/cm²).

As can be understood from FIG. 2, in the GaN HFET of the comparative example having the AlGaN barrier layer in which those Cu concentrations (atomicity/cm²) in the surface region were over 1.0×10¹⁰ (atomicity/cm²), the collapse value resulted in 1.44 to 1.54, that is, all of the collapse values were beyond 1.3.

In contrast to this, according to one example of the nitride semiconductor device (GaN HFET) including the group III nitride semiconductor multilayer substrate 100 of this embodiment, a collapse value of 1.18 was able to be achieved. Also, in another example in which the Cu concentration (atomicity/cm²) was lower than the detection limit by the TXRF method, a collapse value of 1.10 was able to be achieved.

For nitride semiconductor devices (GaN HFETs), attaining a collapse value of 1.3 or lower is of importance in order that the devices are established as commercial products. That is, GaN HFETs having a collapse value of 1.3 or lower have commercial values in terms of performance and cost as a product capable of larger current driving than silicon devices and suitable for high-temperature operations.

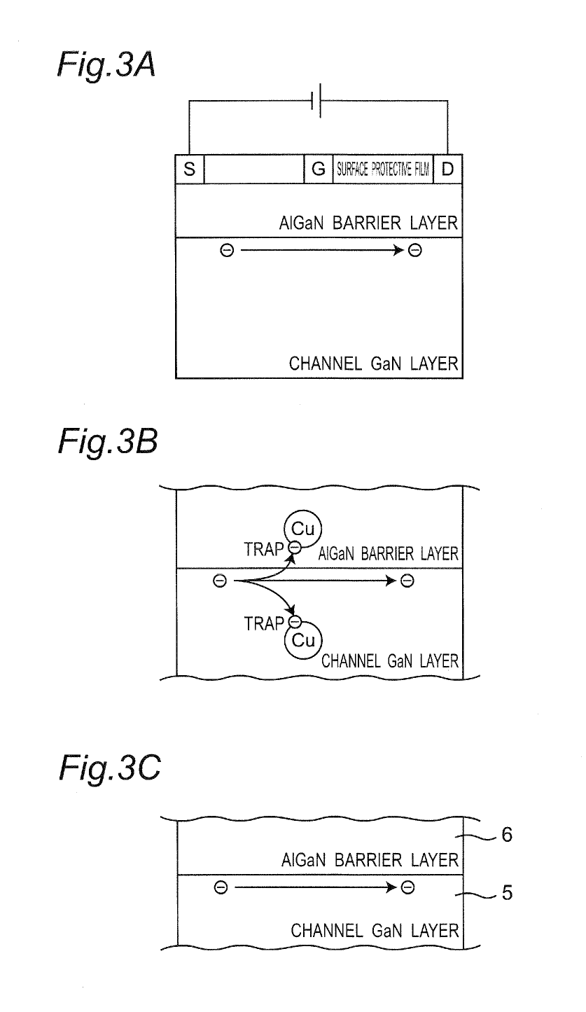

As schematically shown in FIG. 3A, such a voltage is applied to between drain electrode D and source electrode S that the drain D goes a high potential, and the voltage of the gate electrode G is set to zero. Then, electrons run in a direction from the source toward the drain through the 2DEG (2-Dimensional Electron Gas) layer formed between the AlGaN barrier layer and the channel GaN layer. In this case, as schematically shown in FIG. 3B, it can be considered that with Cu (copper) contained in the AlGaN barrier layer, electrons are trapped at deeper levels of Cu so that the drain current decreases, causing the on-resistance to increase with the result that the collapse value is increased. In contrast to this, according to the group III nitride semiconductor multilayer substrate 100 of this embodiment, it can be considered that since the Cu concentration (atomicity/cm² in n the surface region of the AlGaN barrier layer 6 is reduced to 1.0×10¹⁰ (atomicity/cm²) or lower, electrons trapped to Cu are reduced so that the drain current can be increased, causing the on-resistance to decrease with the result that the collapse value can be suppressed as schematically shown in FIG. 3C.

### Second Embodiment

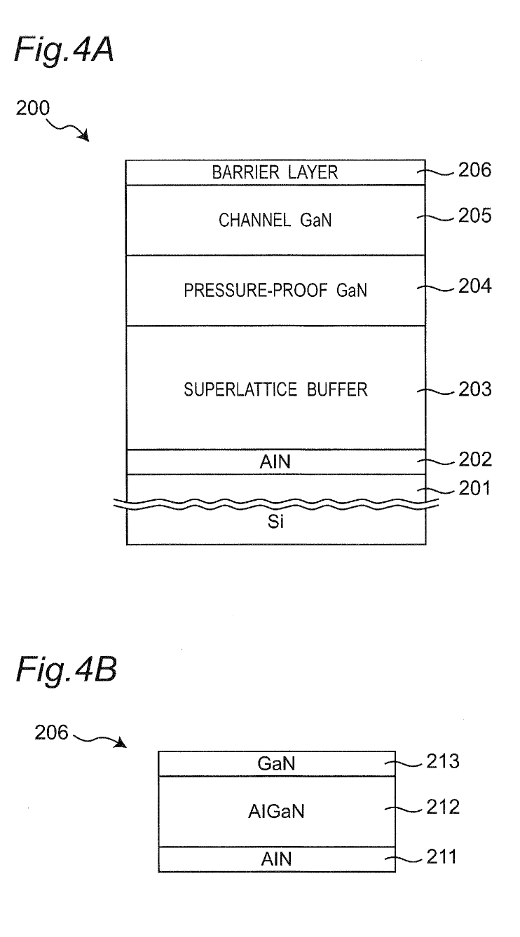

FIG. 4A is a sectional view of a group III nitride semiconductor multilayer substrate 200 according to a second embodiment of the invention.

In this group III nitride semiconductor multilayer substrate 200 of the second embodiment, an AlN seed layer 202, a superlattice buffer layer 203, a pressure-proof use carbon-doped GaN layer 204, a channel GaN layer 205 as an example of a channel layer, and a barrier layer 206 are formed sequentially on a Si substrate 201.

The Si substrate 201, the AlN seed layer 202, the superlattice layer 203, the carbon-doped GaN layer 204, the channel GaN layer 205 and the barrier layer 206 constitute the group III nitride semiconductor multilayer substrate 200.

On the barrier layer 206 of the group III nitride semiconductor multilayer substrate 200, although not shown, a source electrode, a drain electrode, a gate electrode and an insulating film are formed, as in the case of the first embodiment described above. The source electrode, the drain electrode, the gate electrode and the insulating film are fabricated in the same manner as in the above-described first embodiment. As a result, a GaN HFET as the nitride semiconductor device is fabricated.

In this second embodiment, as an example, the film thickness of the AlN seed layer 202 was set to 120 nm, the film thickness of the superlattice buffer layer 203 was set to 2300 nm, and the film thickness of the pressure-proof use carbon-doped GaN layer 204 was set to 840 nm.

Also in this second embodiment, as shown in FIG. 4B, the barrier layer 206 is made up by forming a 1 nm thick AlN hetero-characteristic improving layer 211, a 34 nm thick AlGaN barrier layer 212, and a 1 nm thick GaN cap layer 213 sequentially on the channel GaN layer 205.

The energy band gap of AlN forming the AlN hetero-characteristic improving layer 211 is as large as 6.2 eV, so that an excessively large film thickness would inhibit the hetero-characteristic improving layer from functioning as a hetero junction. Therefore, the hetero-characteristic improving layer is set to such a thickness that enough carrier transport can be fulfilled by the tunnel effect, while an interface steepness between the channel GaN layer 5 and the AlGaN barrier layer 212 is maintained. Thus, the film thickness of the AlN hetero-characteristic improving layer 211 is preferably set to 1 molecular layer to 4 molecular layer.

According to the second embodiment, by the formation of the AlN hetero-characteristic improving layer 211 between the channel GaN layer 205 and the AlGaN barrier layer 212, the interface steepness between the channel GaN layer 205 and the AlGaN barrier layer 212 is improved. As a result, the carrier concentration of the two-dimensional electron gas generated at the heterointerface can be made large, so that the electrical characteristics can be improved.

Also, by the interposition of the AlN hetero-characteristic improving layer 211 between the channel GaN layer 205 and the AlGaN barrier layer 212, it becomes possible to reduce leakage currents. For example, setting the film thickness of the AlN hetero-characteristic improving layer 211 to 10A to 30A made it possible to reduce the leakage currents.

Also according to the second embodiment, by the GaN cap layer 213 formed on the AlGaN barrier layer 212, oxidation of the nitride semiconductor layers (channel GaN layer 205, AlGaN barrier layer 212) can be prevented so that characteristic deteriorations due to oxidation of the nitride semiconductor layers can be suppressed.

In addition, the barrier layer 206 may include either one of the AlN hetero-characteristic improving layer 211 and the GaN cap layer 213.

In this group III nitride semiconductor multilayer substrate 200 of the second embodiment, the Cu concentration in an upper-side region of the barrier layer 206 is 1.0×10¹⁰ (atomicity/cm²) or less. More specifically, in the barrier layer 206, the Cu concentration in a surface region of 10 nm or less depths from the surface is 1.0×10¹⁰ (atomicity/cm²) or less. The Cu concentration in the surface region of the barrier layer 206 was measured by the TXRF method. In this case, the term ‘surface region’ refers to a region of part of the AlGaN barrier layer 206 having a length of 10 nm or less in a direction parallel to the layer thickness direction of the AlGaN barrier layer 206 from its gate electrode 9 side surface toward the channel layer 205 side.

In the nitride semiconductor device constituted as described above, a two-dimensional electron gas (2DEG) is generated at the interface between the channel GaN layer 205 and the barrier layer 206, by which a channel is formed. This channel is controlled by applying a voltage to the gate electrode (not shown) so as to turn on and off the HFET including the source electrode, the drain electrode and the gate electrode, which are not shown. This HFET is a normally-ON type transistor in which while a negative voltage is applied to the gate electrode (not shown), a depletion layer is formed in the channel GaN layer 205 under the gate electrode so that the transistor is turned off, and in which while the voltage of the gate electrode is zero volts, no depletion layer is formed in the channel GaN layer 205 under the gate electrode so that the transistor is turned on.

The group III nitride semiconductor multilayer substrate 200 of this second embodiment was fabricated with the MOCVD device described with reference to FIGS. 5 and FIGS. 6A to 6D, as in the case of the above-described group III nitride semiconductor multilayer substrate 100 of the first embodiment.

That is, a Si substrate 201 is cleaned with a 10% HF (Hydrofluoric acid) solution and thereafter introduced into the MOCVD device. The Si substrate 201 is heated to a substrate temperature of 1100° C. in a hydrogen atmosphere with a flow rate of 10 slm, thus subjected to surface cleaning. Then, an AlN seed layer 202, a superlattice buffer layer 203, a pressure-proof use carbon-doped GaN layer 204, a channel GaN layer 205, and an AlGaN barrier layer 206 are stacked sequentially on the Si substrate 201.

In this case, the AlN seed layer 202 was grown with a growth pressure of 13.3 kPa and a substrate temperature of 1100° C. In addition, as materials of AlN to form the AlN seed layer 202, TMA (trimethylaluminum) with a flow rate of 100 μmol/min. and NH₃ (ammonia) with a flow rate of 12.5 slm were supplied.

The superlattice buffer layer 203 was grown with a growth pressure of 13.3 kPa and a substrate temperature of 1100° C., as in the case of the AlN seed layer 202. For formation of the superlattice buffer layer 203, materials to be supplied are alternately switched over so that AlN and Al_{0.1}Ga_{0.9}N are stacked in layers. As an example, a superlattice layer composed of a 3 nm thick layer of AlN and a 20 nm thick layer of Al_{0.1}Ga_{0.9}N are stacked in repetitions of 100 times to form the superlattice buffer layer 203. As materials of Al_{0.1}Ga_{0.9}N, TMA with a flow rate of 80 μmol/min., TMG (trimethylgallium) with a flow rate of 720 μmol/min. and NH₃ with a flow rate of 12.5 slm are supplied. In addition, materials for AlN of the superlattice buffer layer 203 were supplied as in the case of the AlN seed layer 202.

The carbon-doped GaN layer 204 was grown with a growth pressure of 13.3 kPa and a substrate temperature of 1100° C. as in the case of the AlN seed layer 202. In this case, as materials of GaN serving as the carbon-doped GaN layer 204, TMG with a flow rate of 720 μmol/min. and NH₃ with a flow rate of 12.5 slm are supplied.

The channel GaN layer 205 was grown with a growth pressure of 100 kPa and a substrate temperature of 1100° C. In this case, as materials of GaN serving as the channel GaN layer 205, TMG with a flow rate of 100 μmol/min. and NH₃ with a flow rate of 12.5 slm are supplied. The layer thickness of the channel GaN layer 205 was set to 800 nm as an example.

The barrier layer 206 was grown with a growth pressure of 13.3 kPa and a substrate temperature of 1100° C. as in the case of the AlN seed layer 202. In this case, as materials of the AlN hetero-characteristic improving layer 211 forming the barrier layer 206, TMA (trimethylaluminum) with a flow rate of 100 μmol/min. and NH₃ (ammonia) with a flow rate of 12.5 slm were supplied. Also, materials of the Al_{0.17}Ga_{0.83}N barrier layer 212 forming the barrier layer 206, TMA with a flow rate of 8 μmol/min., TMG with a flow rate of 50 μmol/min., and NH₃ with a flow rate of 12.5 slm were supplied. For the GaN layer 213 forming the barrier layer 206, TMG with a flow rate of 100 μmol/min. and NH₃ with a flow rate of 12.5 slm are supplied.

Next, with use of epitaxial wafers fabricated as described above, a source electrode, a drain electrode and a gate electrode, which are not shown, are formed on the barrier layer 206. The manufacturing method for the source electrode, the drain electrode and the gate electrode is not particularly limited and a known method such as vapor deposition is used, as in the case of the foregoing first embodiment. Also for the insulating film, as in the first embodiment, an insulating film made from SiN is formed on the barrier layer 206 by a known method such as plasma CVD.

Also, as in the foregoing first embodiment, the order for formation of the source electrode, the drain electrode, the gate electrode and the insulating film is not particularly limited, and the insulating film may be formed first. Further, the ohmic electrode metal may be Hf/Al/Hf/Au or Ti/Al/Mo/Au.

Also in this group III nitride semiconductor multilayer substrate 200 of the second embodiment, as in the foregoing first embodiment, in the barrier layer 206, the Cu concentration in a surface region of 10 nm or less depths from the surface is 6.8×10⁹ (atomicity/cm²), which is not more than 1.0×10¹⁰ (atomicity/cm²). The Cu concentration in the surface region of the barrier layer 206 was measured by the TXRF method.

As shown in FIG. 2, since the Cu concentration in the surface region of 10 nm or less depths from the surface of the barrier layer 206 is set to 6.8×10⁹ (atomicity/cm²), which is not more than 1.0×10¹⁰ (atomicity/cm²), the collapse value of the nitride semiconductor device (GaN HFET) including the group III nitride semiconductor multilayer substrate 200 of this embodiment can be set to 1.20, which is not more than 1.3. This GaN HFET with its collapse value which is not more than 1.3 has commercial values in terms of performance and cost as a product capable of larger current driving than silicon devices and suitable for high-temperature operations.

For example, in cascode connection circuits in which a GaN HFET and a Si MOSFET are connected in series, suppressing fluctuations in the resistance value and achieving a lower resistance by using a GaN HFET having a collapse value which is not more than 1.3 is important to fulfill stable circuit operations.

The first, second embodiments have been described on group III nitride semiconductor multilayer substrates using a Si substrate. However, without being limited to the Si substrate, it is also allowable to use a sapphire substrate or SiC substrate, where nitride semiconductor layers may be grown on the sapphire substrate or SiC substrate, or a nitride semiconductor layer may be grown on a substrate formed from a nitride semiconductor such as growing an AlGaN layer on a GaN substrate. Furthermore, the buffer layer may be absent between the substrate and the nitride semiconductor layer.

The first, second embodiments also have been described on HFETs of the normally-ON type. Instead, the invention may also be applied to nitride semiconductor devices of the normally-OFF type. Further, without being limited to nitride semiconductor devices in which the gate electrode is a Schottky electrode, the invention may also be applied to field effect transistors of the insulated-gate structure.

Further, the nitride semiconductor device fabricated by using the group III nitride semiconductor multilayer substrate of this invention is not limited to HFETs using 2DEG and may be applied also to field effect transistors of other structures, in which case also similar effects can be obtained.

The nitride semiconductor for the group III nitride semiconductor multilayer substrate of this invention needs only to be those expressed by AlₓIn_{y}Ga_{1-x-y}N (x≧0, y≧0, 0≦x+y≦1).

Although specific embodiments of the present invention have been described hereinabove, yet the invention is not limited to the above embodiments and may be carried out as they are changed and modified in various ways within the scope of the invention.

### REFERENCE SIGNS LIST

1, 201 Si substrate
2, 202 AlN seed layer
3 superlattice layer
4 carbon-doped GaN layer
5, 205 channel GaN layer
6 AlGaN barrier layer
7 source electrode
8 drain electrode
9 gate electrode
10 insulating film
20 buffer layer
100, 200 group III nitride semiconductor multilayer substrate
101 chamber
102 reaction part
102A upstream-side opening
102B downstream end
111 exhaust part
112 gas introducing part
113 exhaust pipe
113A, 114A, 117A, 118A, 140A, 161A flange
114 exhaust duct
115 copper gasket
117 gas introducing cylinder
118 lid member
120 O-ring
122 mounting plate
125 material gas introducing duct
127, 128, 129 flow regulating valve
130 substrate
131 TMG supply source
132 TMA supply source
133 NH₃ supply source
135 heater
136, 138 current supply line
137, 139 current leading terminal
140 terminal insertion tube
141 sealing lid
147 dielectric ceramic
150 packing
151, 152, 153 pipe
160 view port part
161 cylinder portion
162 window portion
162A window frame portion
162B heat-resistant glass
163 indium wire
203 superlattice buffer layer
204 pressure-proof use carbon-doped GaN layer
206 barrier layer
211 AlN hetero-characteristic improving layer
212 AlGaN barrier layer
213 GaN cap layer

1. A group III nitride semiconductor multilayer substrate comprising:
a channel layer which is a group III nitride semiconductor; and
a barrier layer which is formed on the channel layer to form a heterointerface in combination with the channel layer and which is a group III nitride semiconductor, wherein
in the barrier layer,
a Cu concentration in a region of 10 nm or less depths from its surface is 1.0×10¹⁰ (atomicity/cm²) or less.

2. The group III nitride semiconductor multilayer substrate as claimed in claim 1, wherein
the channel layer is made from GaN, and
the barrier layer is made from AlGaN.

3. The group III nitride semiconductor multilayer substrate as claimed in claim 1, wherein
the channel layer is made from GaN, and wherein
the barrier layer includes
a layer made from AlGaN and positioned on one side closer to the channel layer, and
a cap layer made from GaN and positioned on the AlGaN layer.

4. A group III nitride semiconductor field effect transistor including
the group III nitride semiconductor multilayer substrate as defined in claim 1, wherein
a source electrode, a drain electrode and a gate electrode are provided on the barrier layer, and
an insulating film is provided over a region where none of the source electrode, the drain electrode and the gate electrode is formed on the barrier layer.

5. A group III nitride semiconductor field effect transistor including
the group III nitride semiconductor multilayer substrate as defined in claim 2, wherein
a source electrode, a drain electrode and a gate electrode are provided on the barrier layer, and
an insulating film is provided over a region where none of the source electrode, the drain electrode and the gate electrode is formed on the barrier layer.

6. A group III nitride semiconductor field effect transistor including
the group III nitride semiconductor multilayer substrate as defined in claim 3, wherein
a source electrode, a drain electrode and a gate electrode are provided on the barrier layer, and
an insulating film is provided over a region where none of the source electrode, the drain electrode and the gate electrode is formed on the barrier layer.
